(19) United States
(12) Patent Application Publication
(10) Pub. No.: US 2021/0320088 A1
(43) Pub. Date: Oct. 14, 2021

(54) LED CHIP INITIAL STRUCTURE, SUBSTRATE STRUCTURE, CHIP TRANSFERRING METHOD AND IMAGE DISPLAY DEVICE

(71) Applicant: ASTI GLOBAL INC., TAIWAN, Taichung City (TW)

(72) Inventors: CHIEN-SHOU LIAO, New Taipei City (TW); TE-FU CHANG, Taichung City (TW); SHANG-WEI TSAI, Taoyuan City (TW)

(21) Appl. No.: 17/225,065

(22) Filed: Apr. 7, 2021

(30) Foreign Application Priority Data
Apr. 8, 2020 (TW) 109111750

(51) Int. Cl. H01L 25/075; H01L 23/00; H01L 33/62; H05K 1/02

(52) U.S. Cl. CPC H01L 25/0753; H01L 24/81; H01L 33/62; H05K 1/0212; H01L 2224/81085; H01L 2224/81192; H01L 2933/0066; H01L 2224/81815; H01L 2224/81986; H01L 2224/81238

(57) ABSTRACT

An LED chip initial structure, a substrate structure for carrying the LED chip initial structure, a chip transferring method using the LED chip initial structure, and an LED image display device manufactured by the LED chip transferring method are provided. The LED chip initial structure includes an LED chip main body and a conductive electrode. One of a top side and a bottom side of the LED chip main body is a temporary electrodeless side, another one of the top side and the bottom side of the LED chip main body is a connecting electrode side, and the temporary electrodeless side has an unoccupied surface. The conductive electrode is disposed on the connecting electrode side of the LED chip main body so as to electrically connect to the LED chip main body. The LED chip initial structure is adhered to a hot-melt material through the conductive electrode.

### CROSS-REFERENCE TO RELATED PATENT APPLICATION

This application claims the benefit of priority to Taiwan Patent Application No. 109111750, filed on Apr. 8, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip initial structure, a substrate structure, a chip transferring method and an image display device, and more particularly to an LED (light emitting diode) chip initial structure, a substrate structure for carrying the LED chip initial structure, an LED chip transferring method using the LED chip initial structure, and an LED image display device manufactured by the LED chip transferring method.

### BACKGROUND OF THE DISCLOSURE

Currently, a vertical LED chip includes two conductive electrodes respectively disposed on two opposite sides thereof. However, without any one of the two conductive electrodes, the vertical LED chip will become useless for lighting purpose. In addition, sizes of LED chips are getting smaller and smaller, so that it is difficult to use a nozzle to classify or bond the miniaturized LED chips.

### SUMMARY OF THE DISCLOSURE

In response to the above-referenced technical inadequacy, the present disclosure provides an LED chip initial structure, a substrate structure, a chip transferring method and an image display device.

In one aspect, the present disclosure provides an LED chip initial structure including an LED chip main body and a conductive electrode. The LED chip main body has a top side and a bottom side that are opposite to each other. One of the top side and the bottom side of the LED chip main body is a temporary electrodeless side, another one of the top side and the bottom side of the LED chip main body is a connecting electrode side, and the temporary electrodeless side has an unoccupied surface. The conductive electrode is disposed on the connecting electrode side of the LED chip main body so as to electrically connect to the LED chip main body. The LED chip initial structure is applied to adhere to a hot-melt material through the conductive electrode.

In another aspect, the present disclosure provides a substrate structure including a circuit substrate for carrying a plurality of hot-melt materials and a micro heater group disposed on or inside the circuit substrate.

In yet another aspect, the present disclosure provides a chip transferring method including: distributing a plurality of LED chip initial structures in a liquid substance of a liquid receiving tank, and placing a substrate structure in the liquid receiving tank, each of the LED chip initial structures including an LED chip main body and a first conductive electrode, the LED chip main body having a temporary electrodeless side and a connecting electrode side, the first conductive electrode being disposed on the connecting electrode side of the LED chip main body, and the substrate structure including a circuit substrate for carrying a plurality of hot-melt materials and a micro heater group disposed on or inside the circuit substrate; and then melting the hot-melt materials by heating of the micro heater group, so that the first conductive electrode of each of the LED chip initial structures is adhered to the corresponding hot-melt material that has been melted.

More particularly, the hot-melt materials respectively serve as a plurality of first conductive layers that are applied to respectively electrically connect the first conductive electrodes to the circuit substrate. After the step of melting the hot-melt materials by heating of the micro heater group, the method further includes separating the substrate structure with the LED chip initial structures from the liquid receiving tank; respectively forming a plurality of second conductive electrodes on the temporary electrodeless sides of the LED chip main bodies; and then forming a plurality of second conductive layers for respectively electrically connecting the second conductive electrodes to the circuit substrate.

In yet another aspect, the present disclosure provides an image display device including a substrate structure, an LED chip group and a conductive connection structure. The substrate structure includes a circuit substrate and a micro heater group disposed on or inside the circuit substrate. The LED chip group includes a plurality of LED chip structures electrically connected to the circuit substrate. Each of the LED chip structures includes an LED chip main body, a first conductive electrode disposed on a bottom side of the LED chip main body, and a second conductive electrode disposed on a top side of the LED chip main body. The conductive connection structure includes a plurality of first conductive layers and a plurality of second conductive layers. Each of the first conductive layers is electrically connected between the first conductive electrode of the corresponding LED chip structure and the circuit substrate, and each of the second conductive layers is electrically connected between the second conductive electrode of the corresponding LED chip structure and the circuit substrate. The first conductive electrode layer is at least made of a hot-melt material, the hot-melt material at least includes a first solder material and a second solder material, and a melting point of the first solder material is the same as or different from a melting point of the second solder material.

Therefore, by virtue of “an LED chip main body having a top side and a bottom side that are opposite to each other, one of the top side and the bottom side of the LED chip main body being a temporary electrodeless side, another one of the top side and the bottom side of the LED chip main body being a connecting electrode side, and the temporary electrodeless side having an unoccupied surface” and “a conductive electrode being disposed on the connecting electrode side of the LED chip main body so as to electrically connect to the LED chip main body”, the LED chip initial structure can be adhered to a hot-melt material through the conductive electrode.

Furthermore, by virtue of “a circuit substrate for carrying a plurality of hot-melt materials” and “a micro heater group being disposed on or inside the circuit substrate”, each of the LED chip initial structures can be adhered to the corresponding hot-melt material that has been melted by heating of the micro heater group.

Moreover, by virtue of “distributing a plurality of LED chip initial structures in a liquid substance of a liquid receiving tank, each of the LED chip initial structures including an LED chip main body and a first conductive electrode, the LED chip main body having a temporary electrodeless side and a connecting electrode side, and the first conductive electrode being disposed on the connecting electrode side of the LED chip main body”, “placing a substrate structure in the liquid receiving tank, and the substrate structure including a circuit substrate for carrying a plurality of hot-melt materials and a micro heater group disposed on or inside the circuit substrate” and “melting the hot-melt materials by heating of the micro heater group”, the first conductive electrode of each of the LED chip initial structures can be adhered to the corresponding hot-melt material that has been melted by heating.

In addition, by virtue of “the substrate structure including a circuit substrate and a micro heater group disposed on or inside the circuit substrate”, “the LED chip group including a plurality of LED chip structures electrically connected to the circuit substrate, each of LED chip structures including an LED chip main body, a first conductive electrode disposed on a bottom side of the LED chip main body, and the second conductive electrode disposed on a top side of the LED chip main body”, “each of the first conductive layers being electrically connected between the first conductive electrode of the corresponding LED chip structure and the circuit substrate, and each of the second conductive layers being electrically connected between the second conductive electrode of the corresponding LED chip structure and the circuit substrate” and “the first conductive layers being respectively made of the hot-melt materials, each of the hot-melt materials at least including a first solder material and a second solder material, and a melting point of the first solder material being the same as or different from a melting point of the second solder material”, the first conductive electrode of each of the LED chip structures can be electrically connected to the circuit substrate through the corresponding first conductive layer that is formed by mixing the first solder material and a second solder material.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a plurality of LED initial structures being formed on a base material layer according to a first embodiment of the present disclosure;

FIG. 2 is a schematic view of the base material layer being removed so as to separate the LED initial structures from each other according to the first embodiment of the present disclosure;

FIG. 3 is a schematic view of a plurality of red LED chip initial structures being respectively adhered to a plurality of first hot-melt materials according to a second embodiment of the present disclosure;

FIG. 4 is a schematic view of a first driving circuit being electrically connected to a plurality of first micro heaters according to the second embodiment of the present disclosure;

FIG. 5 is a schematic view of a plurality of green LED chip initial structures being respectively adhered to a plurality of second hot-melt materials according to the second embodiment of the present disclosure;

FIG. 6 is a schematic view of a second driving circuit being electrically connected to a plurality of second micro heaters according to the second embodiment of the present disclosure;

FIG. 7 is a schematic view of a plurality of blue LED chip initial structures being respectively adhered to a plurality of third hot-melt materials according to the second embodiment of the present disclosure;

FIG. 8 is a schematic view of a third driving circuit being electrically connected to a plurality of third micro heaters according to the second embodiment of the present disclosure;

FIG. 9 is a schematic view of a second conductive electrode being formed on an LED chip main body according to the second embodiment of the present disclosure;

FIG. 10 is a schematic view of a conductive electrode of an LED chip initial structure being adhered to a second solder material that has been melted by heating of a micro heater according to the second embodiment of the present disclosure;

FIG. 11 is a schematic view of a conductive layer formed by concurrently heating a first solder material and a second solder material according to the second embodiment of the present disclosure;

FIG. 12 is a schematic view of a first image display device according to a third embodiment of the present disclosure;

FIG. 13 is a schematic view of a second image display device according to the third embodiment of the present disclosure; and

FIG. 14 is a schematic view of a third image display device according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

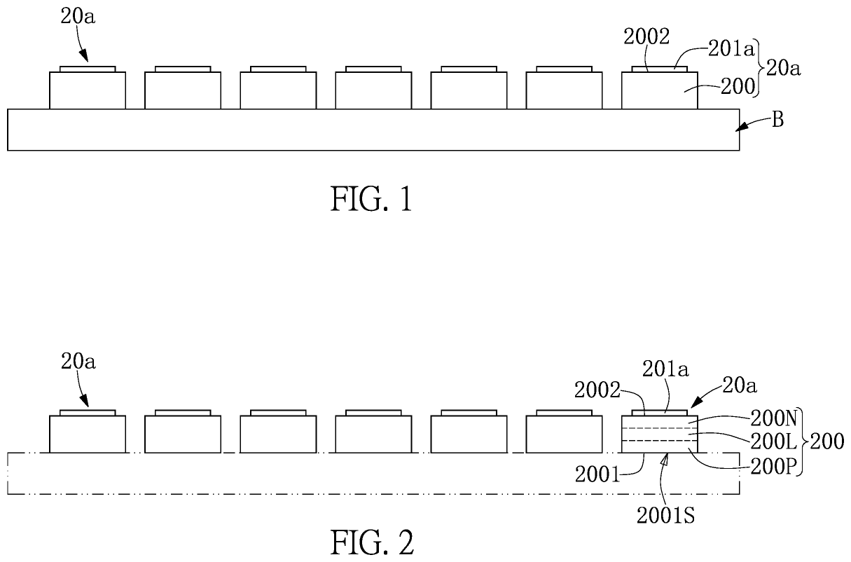

Referring to FIG. 1 and FIG. 2, a first embodiment of the present disclosure provides an LED chip initial structure 20a and a method of manufacturing the same. The method of manufacturing the LED chip initial structure 20a includes the following steps: as shown in FIG. 1, forming a plurality of LED initial structures 20a on a base material layer B, each of the LED initial structures 20a including an LED chip main body 200 and a conductive electrode 201a; next, referring to FIG. 1 and FIG. 2, removing the base material layer B so as to separate the LED initial structures 20a from each other. Hence, the LED initial structure 20a includes only one conductive electrode 201a disposed on a surface thereof, and there is no conductive electrode disposed on another surface of the LED initial structures 20a. For example, the base material layer B can be a wafer or a sapphire. However, the aforementioned description is merely an example and is not meant to limit the scope of the present disclosure.

More particularly, as shown in FIG. 2, the LED initial structure 20a includes an LED chip main body 200 and a conductive electrode 201a. Moreover, the LED chip main body 200 has a top side and a bottom side that are opposite to each other, one of the top side and the bottom side of the LED chip main body 200 is a temporary electrodeless side 2001, and another one of the top side and the bottom side of the LED chip main body 200 is a connecting electrode side 2002. In addition, the conductive electrode 201a is disposed on the connecting electrode side 2002 of the LED chip main body 200 so as to electrically connect to the LED chip main body 200. For example, the bottom side of the LED chip main body 200 is the temporary electrodeless side 2001, and the top side of the LED chip main body 200 is the connecting electrode side 2002. It should be noted that the temporary electrodeless side 2001 has an unoccupied surface 2001S that is exposed out of the LED initial structures 20a, and the unoccupied surface 2001S of the temporary electrodeless side 2001 is unoccupied temporarily by any electrode structure. In addition, the conductive electrode 201a has a conductive surface corresponding to the unoccupied surface 2001S. However, the aforementioned description is merely an example and is not meant to limit the scope of the present disclosure.

For example, as shown in FIG. 2, the LED chip main body 200 includes a p-type semiconductor layer 200P, a light-emitting layer 200L disposed on the p-type semiconductor layer 200P, and an n-type semiconductor layer 200N disposed on the light-emitting layer 200L. In addition, the conductive electrode 201a (and the connecting electrode side 2002) is electrically connected to one of the p-type semiconductor layer 200P and the n-type semiconductor layer 200N, and the temporary electrodeless side 2001 is electrically connected to another one of the p-type semiconductor layer 200P and the n-type semiconductor layer 200N. For example, as shown in FIG. 2, the conductive electrode 201a can be electrically connected to the n-type semiconductor layer 200N, and the temporary electrodeless side 2001 can be electrically connected to the p-type semiconductor layer 200P. However, the aforementioned description is merely an example and is not meant to limit the scope of the present disclosure.

### Second Embodiment

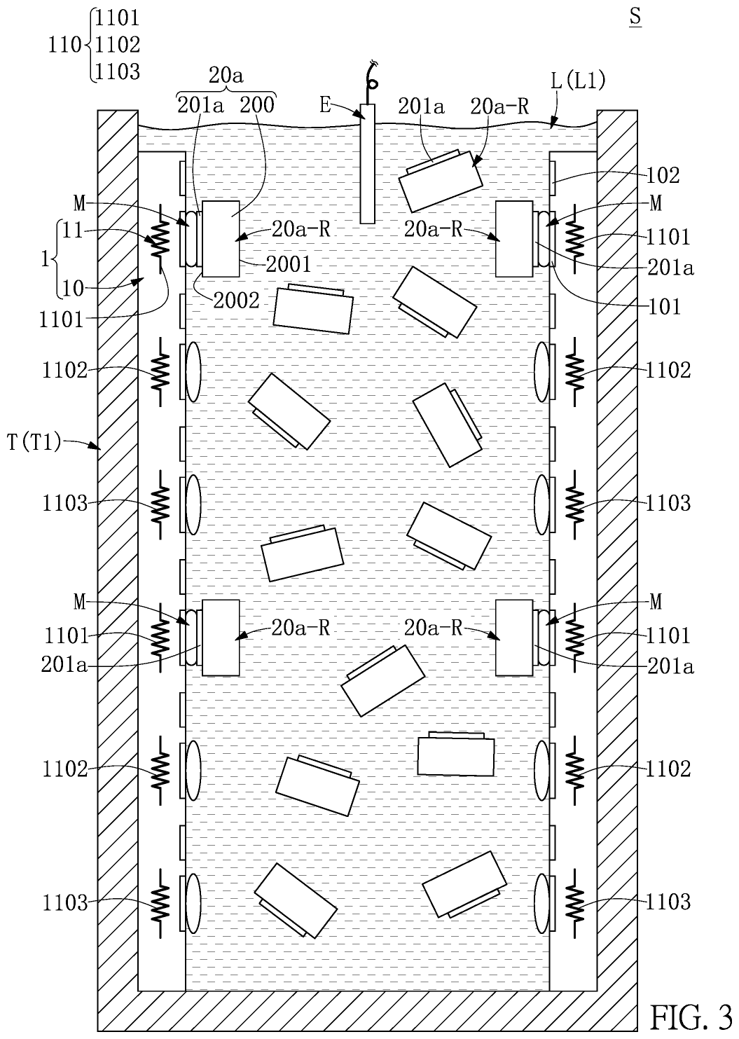

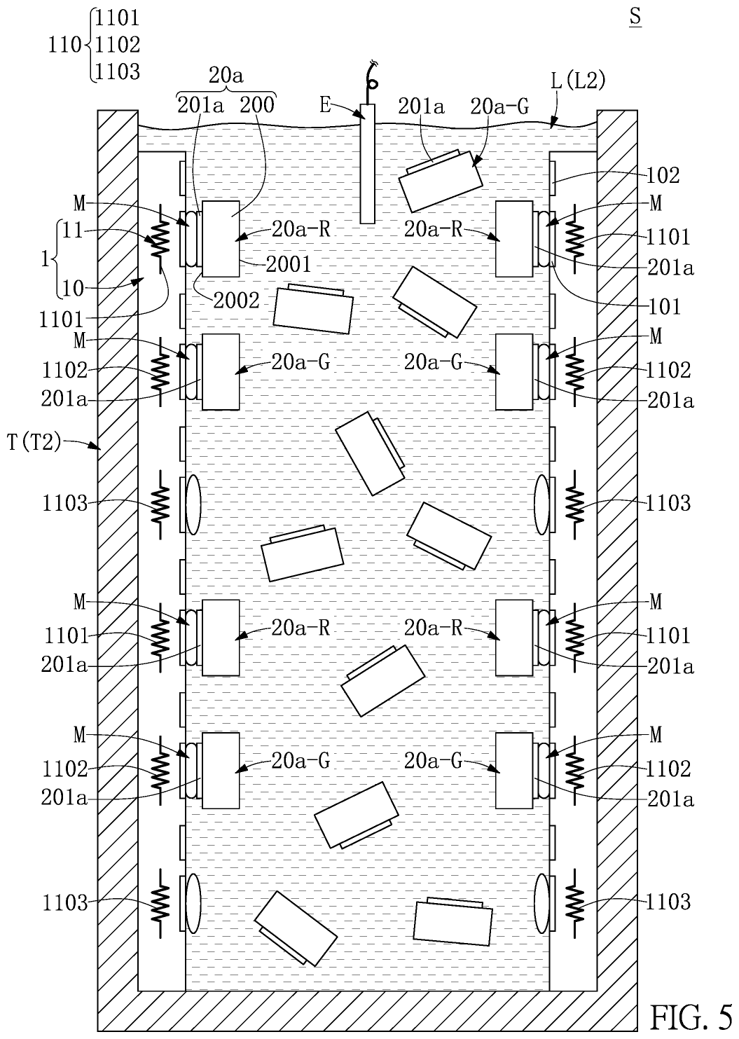

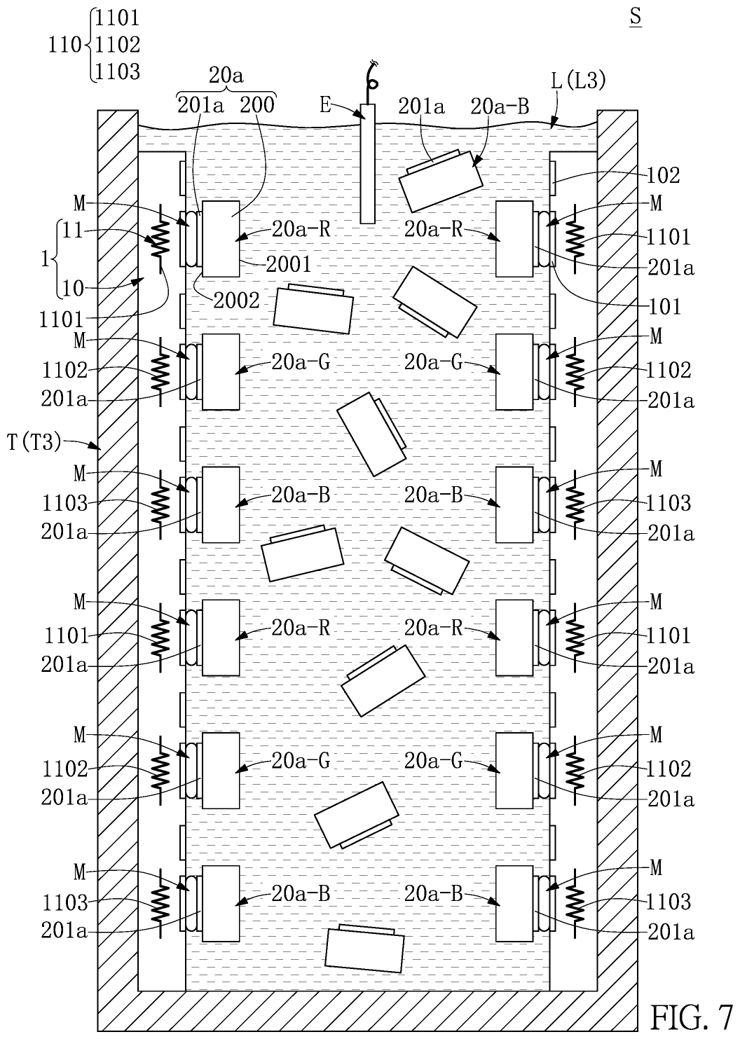

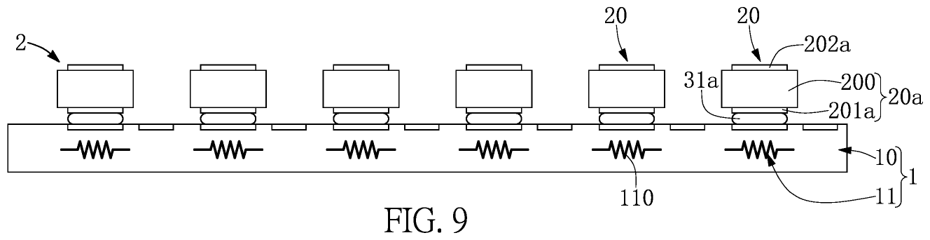

Referring to FIG. 3 to FIG. 9, a second embodiment of the present disclosure provides a chip classifying system S including a liquid receiving tank T and a substrate structure 1. Referring to FIG. 3, FIG. 5 and FIG. 7, the liquid receiving tank T includes a liquid substance L (such as water or any mixing liquid containing water) received therein, and a plurality of LED chip initial structures 20a can be randomly distributed in the liquid substance L of the liquid receiving tank T. In addition, referring to FIG. 7 and FIG. 9, the substrate structure 1 can be movably disposed (placed) in the liquid receiving tank T (as shown in FIG. 7) or separated from the liquid receiving tank T (as shown FIG. 9), and the substrate structure 1 includes a circuit substrate 10 and a micro heater group 11 disposed on or inside the circuit substrate 10.

For example, referring to FIG. 3, FIG. 5, FIG. 7 and FIG. 9, the substrate structure 1 can be a rigid circuit board or a flexible circuit board. In addition, each of the LED chip initial structures 20a includes an LED chip main body 200 and a conductive electrode 201a (such as a first conductive electrode). The LED chip main body 200 has a temporary electrodeless side 2001 and a connecting electrode side 2002 that are opposite to each other, and the conductive electrode 201a (such as the first conductive electrode) is disposed on the connecting electrode side 2002 of the LED chip main body 200 so as to electrically connect to the LED chip main body 200. However, the aforementioned description is merely an example and is not meant to limit the scope of the present disclosure.

For example, referring to FIG. 3, FIG. 5, FIG. 7 and FIG. 9, the substrate structure 1 includes a circuit substrate 10 for carrying a plurality of hot-melt materials M and a micro heater group 11 disposed on or inside the circuit substrate 10, and the circuit substrate 10 includes a plurality of first conductive pads 101 and a plurality of second conductive pads 102 respectively corresponding to the first conductive pads 101. In addition, the hot-melt materials M are respectively disposed on the first conductive pads 101 of the circuit substrate 10, and the melting point of a part of the hot-melt materials M and the melting point of another part of the hot-melt materials M can be the same or different (that is to say, the hot-melt materials M have the same melting point or at least two different melting points). Moreover, the micro heater group 11 includes a plurality of driving circuits and a plurality of micro heaters 110 respectively corresponding to the hot-melt materials M, one of the driving circuits is electrically connected to a part of the micro heaters 110, and another one of the driving circuits is electrically connected to another part of the micro heaters 110. Furthermore, when the substrate structure 1 is movably placed in the liquid receiving tank T, the part of the micro heaters 110 can be concurrently driven by the one of the driving circuits so as to respectively heat the part of the hot-melt materials M, so that the conductive electrodes 201a of the part of the LED chip initial structures 20a can be respectively adhered to the part of the hot-melt materials M. In addition, when the substrate structure 1 is movably placed in the liquid receiving tank T, the another part of the micro heaters 110 can be concurrently driven by the another one of the driving circuits so as to respectively heat the another part of the hot-melt materials M, so that the conductive electrodes 201a of the another part of the LED chip initial structures 20a can be respectively adhered to the another part of the hot-melt materials M. It should be noted that the chip classifying system S further includes a temperature control device E (such as a heating rod or a temperature sensor) that can be placed in the liquid receiving tank T so as to control a temperature of the liquid substance L. However, the aforementioned description is merely an example and is not meant to limit the scope of the present disclosure.

For example, referring to FIG. 3 to FIG. 8, the micro heater group 11 includes a first driving circuit 111, a second driving circuit 112, a third driving circuit 113 and a plurality of micro heaters 110 respectively corresponding to the hot-melt materials M (or the conductive layers 31a as shown in FIG. 9), and the micro heaters 110 are at least divided into a plurality of first micro heaters 1101 concurrently electrically connected to the first driving circuit 111, a plurality of second micro heaters 1102 concurrently electrically connected to the second driving circuit 112, and a plurality of third micro heaters 1103 concurrently electrically connected to the third driving circuit 113. In addition, the LED chip initial structures 20a are at least divided into a plurality of red LED chip initial structures (20a-R), a plurality of green LED chip initial structures (20a-G) and a plurality of blue LED chip initial structures (20a-B). However, the aforementioned description is merely an example and is not meant to limit the scope of the present disclosure.

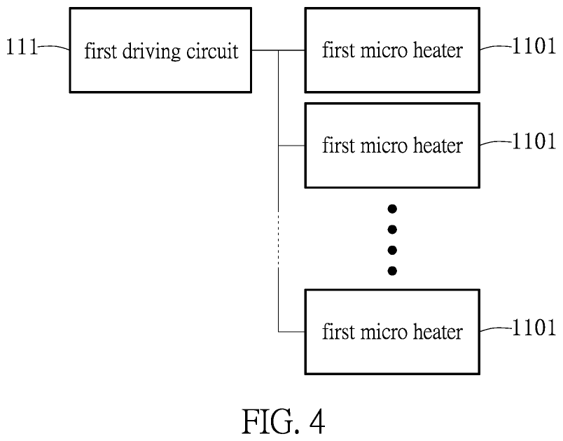

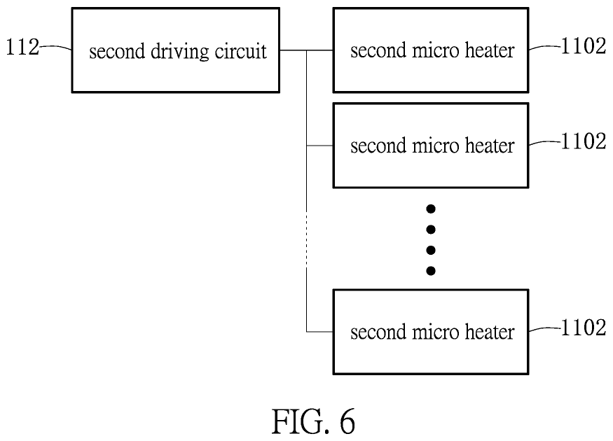

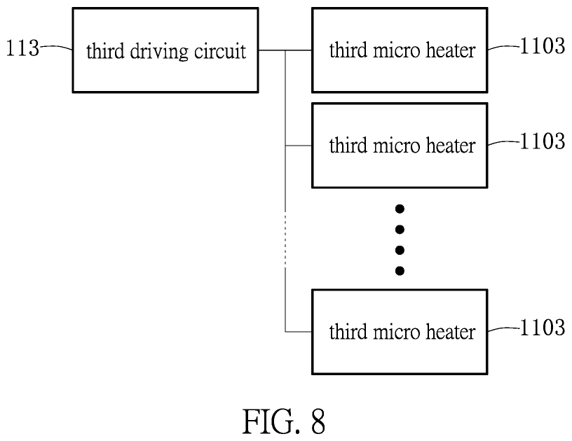

For example, referring to FIG. 3 and FIG. 4, when the red LED chip initial structures (20a-R) are randomly distributed in a first liquid substance L1 of a first liquid receiving tank T1, the first micro heaters 1101 can be concurrently driven by the first driving circuit 111 so as to respectively heat a part of the hot-melt materials M (such as a plurality of first hot-melt materials), and a viscosity of each of the first hot-melt materials M can be increased by heating of the corresponding first micro heater 1101, so that the red LED chip initial structures (20a-R) can be respectively adhered to the first hot-melt materials M. Referring to FIG. 5 and FIG. 6, when the green LED chip initial structures (20a-G) are randomly distributed in a second liquid substance L2 of a second liquid receiving tank T2, the second micro heaters 1102 can be concurrently driven by the second driving circuit 112 so as to respectively heat another part of the hot-melt materials M (such as a plurality of second hot-melt materials), and a viscosity of each of the second hot-melt materials M can be increased by heating of the corresponding second micro heater 1102, so that the green LED chip initial structures (20a-G) can be respectively adhered to the second hot-melt materials M. Referring to FIG. 7 and FIG. 8, when the blue LED chip initial structures (20a-B) are randomly distributed in a third liquid substance L3 of a third liquid receiving tank T3, the third micro heaters 1103 can be concurrently driven by the third driving circuit 113 so as to respectively heat yet another part of the hot-melt materials M (such as a plurality of third hot-melt materials), and a viscosity of each of the third hot-melt materials M can be increased by heating of the corresponding third micro heater 1103, so that the blue LED chip initial structures (20a-B) can be respectively adhered to the third hot-melt materials M. Therefore, in the first liquid substance L1, only the first driving circuit 111 can be used to drive the first micro heater 1101 to respectively heat the first hot-melt materials M, so that the red LED chip initial structures (20a-R) can be respectively adhered to the first hot-melt materials M that have been melted. In the second liquid substance L2, only the second driving circuit 112 can be used to drive the second micro heater 1102 to respectively heat the second hot-melt materials M, so that the green LED chip initial structures (20a-G) can be respectively adhered to the second hot-melt materials M that have been melted. In the third liquid substance L3, only the third driving circuit 113 can be used to drive the third micro heater 1103 to respectively heat the third hot-melt materials M, so that the blue LED chip initial structures (20a-B) can be respectively adhered to the third hot-melt materials M that have been melted. Hence, the red LED chip initial structures (20a-R), the green LED chip initial structures (20a-G) and the blue LED chip initial structures (20a-B) can be sequentially adhered to the circuit substrate 10 of the substrate structure 1. However, the aforementioned description is merely an example and is not meant to limit the scope of the present disclosure.

For example, referring to FIG. 9 to FIG. 11, each of the hot-melt materials M at least includes a first solder material M1 disposed on the circuit substrate 10 and a second solder material M2 disposed on the first solder material M1, and a melting point of the first solder material M1 is the same as or different from a melting point of the second solder material M2. More particularly, when the melting points of the first solder material M1 and the second solder material M2 are different, the first solder material M1 can be a high-temperature solder or any solder material that can be melted at a high temperature (that is to say, the first solder material M1 can be a high temperature solder that has a high melting point), and the second solder material M2 can be a low-temperature solder or any solder material that can be melted at a low temperature (that is to say, the second solder material M2 can be a low temperature solder that has a low melting point). The high melting point can exceed 178° C. or 183° C., and the value thereof can be an arbitrary non-positive integer or an arbitrary positive integer. The low melting point can range from 10 to 40° C. (or from 5 to 30° C., or from 20 to 50° C.) or cannot exceed 178° C. For example, the value of the low melting point can be an arbitrary non-positive integer or an arbitrary positive integer. In addition, when each of the second solder materials M2 is melted by heating of the corresponding micro heater 110, the conductive electrode 201a of each of the LED chip initial structures 20a can be adhered to the corresponding second solder material M2, and the second solder material M2 can be connected between the first solder material M1 and the conductive electrode 201a. Moreover, referring to FIG. 9 to FIG. 11, after the substrate structure 1 is separated from the liquid receiving tank T, both the first solder material M1 and the second solder material M2 of each hot-melt material M can be concurrently heated to form a conductive layer 31a, and each of the conductive layers 31a can be disposed between the corresponding conductive electrode 201a and the corresponding first conductive pads 101. However, the aforementioned description is merely an example and is not meant to limit the scope of the present disclosure.

It should be noted that as shown in FIG. 9, another conductive electrode 202a (such as a second conductive electrode) can be formed on the LED chip main body 200 by coating, printing or a semiconductor process. However, the aforementioned description is merely an example and is not meant to limit the scope of the present disclosure.

### Third Embodiment

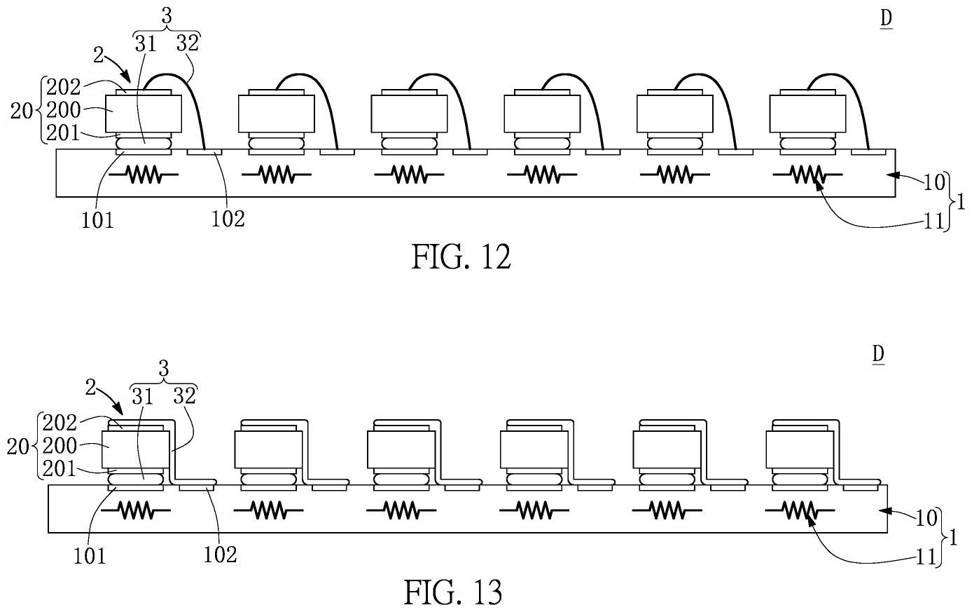

Referring to FIG. 12 to FIG. 14, a third embodiment of the present disclosure provides an image display device D including a substrate structure 1, an LED chip group 2 and a conductive connection structure 3.

Referring to FIG. 12 to FIG. 14, the substrate structure 1 includes a circuit substrate 10 and a micro heater group 11 disposed on or inside the circuit substrate 10, the circuit substrate 10 includes a plurality of first conductive pads 101 and a plurality of second conductive pads 102 respectively corresponding to the first conductive pads 101, and the micro heater group 11 includes a plurality of micro heaters 110. In addition, the LED chip group 2 includes a plurality of LED chip structures 20 electrically connected to the circuit substrate 10, and each of LED chip structures 20 includes an LED chip main body 200, a first conductive electrode 201 disposed on a bottom side of the LED chip main body 200, and a second conductive electrode 202 disposed on a top side of the LED chip main body 200. Moreover, the conductive connection structure 3 includes a plurality of first conductive layers 31 (for example, the first conductive layer 31 can be made of the hot-melt material) and a plurality of second conductive layers 32. Each of the first conductive layers 31 is electrically connected between the first conductive electrode 201 of the corresponding LED chip structure 20 and the circuit substrate 10, and each of the second conductive layers 32 is electrically connected between the second conductive electrode 202 of the corresponding LED chip structure 20 and the circuit substrate 10.

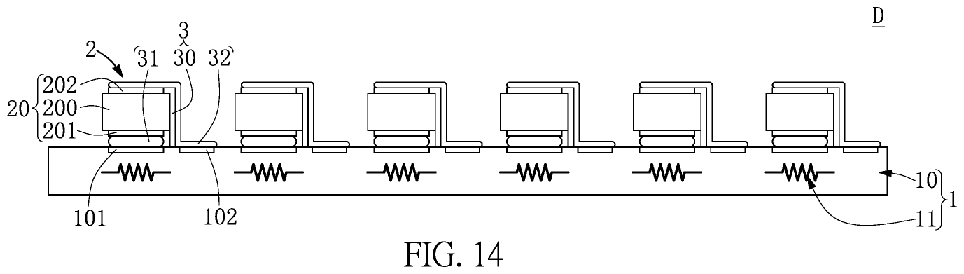

Referring to FIG. 12 to FIG. 14, each of the first conductive layers 31 is electrically connected between the first conductive electrode 201 of the corresponding LED chip structure 20 and the corresponding first conductive pad 101, and each of the second conductive layers 32 is extended from the second conductive electrode 202 of the corresponding LED chip structure 20 to the corresponding second conductive pad 102. For example, each of the second conductive layers 32 can be a conductive wire formed by wire bonding (as shown in FIG. 12) or a conductive layer formed by coating, printing or a semiconductor process (as shown in FIG. 13). It should be noted that as shown in FIG. 14, the conductive connection structure 3 includes a plurality of electric insulating layers 30 (such as insulating barrier layers), and each of the electric insulating layers 30 is disposed between the corresponding LED chip structure 20 and the corresponding second conductive layer 32 so as to insulate the first conductive layer 31 and the second conductive layer 32 from each other. However, the aforementioned description is merely an example and is not meant to limit the scope of the present disclosure.

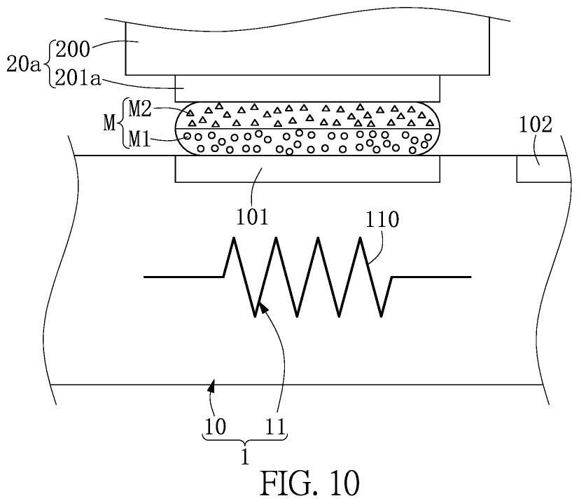

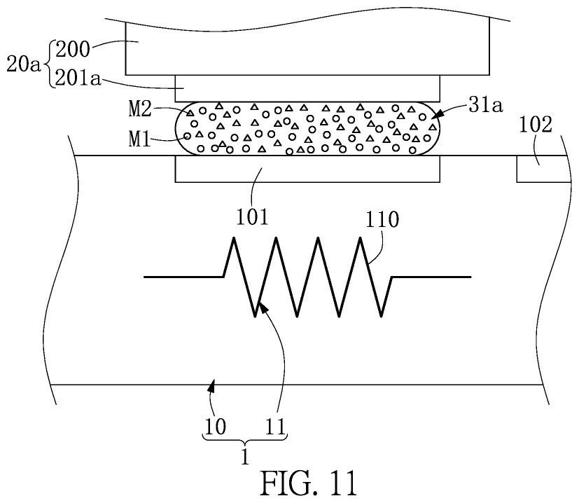

Referring to FIG. 10 to FIG. 11, each of the hot-melt materials 31 at least includes a first solder material M1 and a second solder material M2 that can be mixed together, and a melting point of the first solder material M1 can be the same as or different from a melting point of the second solder material M2. More particularly, when the melting points of the first solder material M1 and the second solder material M2 are different, the first solder material M1 can be a high-temperature solder or any solder material that can be melted at a high temperature (that is to say, the first solder material M1 can be a high temperature solder that has a high melting point), and the second solder material M2 can be a low-temperature solder or any solder material that can be melted at a low temperature (that is to say, the second solder material M2 can be a low temperature solder that has a low melting point). The high melting point can exceed 178° C. or 183° C., and the value thereof can be an arbitrary non-positive integer or an arbitrary positive integer. The low melting point can range from 10 to 40° C. (or from 5 to 30° C., or from 20 to 50° C.) or cannot exceed 178° C. For example, the value of the low melting point can be an arbitrary non-positive integer or an arbitrary positive integer. However, the aforementioned description is merely an example and is not meant to limit the scope of the present disclosure.

### Beneficial Effects of the Embodiments

In conclusion, by virtue of “an LED chip main body 200 having a top side and a bottom side that are opposite to each other, one of the top side and the bottom side of the LED chip main body 200 being a temporary electrodeless side 2001, another one of the top side and the bottom side of the LED chip main body 200 being a connecting electrode side 2002, and the temporary electrodeless side 2001 having an unoccupied surface 2001S” and “a conductive electrode 201a being disposed on the connecting electrode side 2002 of the LED chip main body 200 so as to electrically connect to the LED chip main body 200”, the LED chip initial structure 20a can be adhered to a hot-melt material M through the conductive electrode 201a.

Furthermore, by virtue of “a circuit substrate 10 for carrying a plurality of hot-melt materials M” and “a micro heater group 11 being disposed on or inside the circuit substrate 10”, each of the LED chip initial structures 20a can be adhered to the corresponding hot-melt material M that has been melted by heating of the micro heater group 11.

Moreover, by virtue of “distributing a plurality of LED chip initial structures 20a in a liquid substance L of a liquid receiving tank T, each of the LED chip initial structures 20a including an LED chip main body 200 and a first conductive electrode 201, the LED chip main body 200 having a temporary electrodeless side 2001 and a connecting electrode side 2002, and the first conductive electrode 201 being disposed on the connecting electrode side 2002 of the LED chip main body 200”, “placing a substrate structure 1 in the liquid receiving tank T, and the substrate structure 1 including a circuit substrate 10 for carrying a plurality of hot-melt materials M and a micro heater group 11 disposed on or inside the circuit substrate 10” and “melting the hot-melt materials M by heating of the micro heater group 11”, the first conductive electrode 201 of each of the LED chip initial structures 20a can be adhered to the corresponding hot-melt material M that has been melted by heating.

In addition, by virtue of “the substrate structure 1 including a circuit substrate 10 and a micro heater group 11 disposed on or inside the circuit substrate 10”, “the LED chip group 2 including a plurality of LED chip structures 20 electrically connected to the circuit substrate 10, each of LED chip structures 20 including an LED chip main body 200, a first conductive electrode 201 disposed on a bottom side of the LED chip main body 200, and the second conductive electrode 202 disposed on a top side of the LED chip main body 200”, “each of the first conductive layers 31 being electrically connected between the first conductive electrode 201 of the corresponding LED chip structure 20 and the circuit substrate 10, and each of the second conductive layers 32 being electrically connected between the second conductive electrode 202 of the corresponding LED chip structure 20 and the circuit substrate 10” and “the first conductive layers 31 being respectively made of the hot-melt materials M, each of the hot-melt materials M at least including a first solder material M1 and a second solder material M2, and a melting point of the first solder material M1 being the same as or different from a melting point of the second solder material M2”, the first conductive electrode 201 of each of the LED chip structures 20 can be electrically connected to the circuit substrate 10 through the corresponding first conductive layer 31 that is formed by mixing the first solder material M1 and a second solder material M2.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An LED chip initial structure, comprising:
an LED chip main body having a top side and a bottom side that are opposite to each other, wherein one of the top side and the bottom side of the LED chip main body is a temporary electrodeless side, another one of the top side and the bottom side of the LED chip main body is a connecting electrode side, and the temporary electrodeless side has an unoccupied surface; and
a conductive electrode disposed on the connecting electrode side of the LED chip main body so as to electrically connect to the LED chip main body;
wherein the LED chip initial structure is applied to adhere to a hot-melt material through the conductive electrode.

2. The LED chip initial structure according to claim 1, wherein the LED chip initial structure is applied into a liquid substance of a liquid receiving tank, and the conductive electrode has a conductive surface opposite to the unoccupied surface of the temporary electrodeless side.

3. A substrate structure, comprising: a circuit substrate for carrying a plurality of hot-melt materials and a micro heater group disposed on or inside the circuit substrate.

4. A chip transferring method, comprising:
distributing a plurality of LED chip initial structures in a liquid substance of a liquid receiving tank, and placing a substrate structure in the liquid receiving tank, wherein each of the LED chip initial structures includes an LED chip main body and a first conductive electrode, the LED chip main body has a temporary electrodeless side and a connecting electrode side, the first conductive electrode is disposed on the connecting electrode side of the LED chip main body, and the substrate structure includes a circuit substrate for carrying a plurality of hot-melt materials and a micro heater group disposed on or inside the circuit substrate; and
melting the hot-melt materials by heating of the micro heater group, so that the first conductive electrode of each of the LED chip initial structures is adhered to the corresponding hot-melt material that has been melted.

5. The chip transferring method according to claim 4, wherein the hot-melt materials respectively serve as a plurality of first conductive layers that are applied to respectively electrically connect the first conductive electrodes to the circuit substrate; wherein, after the step of melting the hot-melt materials by heating of the micro heater group, the method further comprises:
separating the substrate structure with the LED chip initial structures from the liquid receiving tank;
respectively forming a plurality of second conductive electrodes on the temporary electrodeless sides of the LED chip main bodies; and
forming a plurality of second conductive layers for respectively electrically connecting the second conductive electrodes to the circuit substrate.

6. The chip transferring method according to claim 4, wherein the LED chip initial structures are at least divided into a plurality of red LED chip initial structures, a plurality of green LED chip initial structures and a plurality of blue LED chip initial structures; wherein the micro heater group includes a first driving circuit, a second driving circuit, a third driving circuit and a plurality of micro heaters respectively corresponding to the hot-melt materials, and the micro heaters are at least divided into a plurality of first micro heaters concurrently electrically connected to the first driving circuit, a plurality of second micro heaters concurrently electrically connected to the second driving circuit, and a plurality of third micro heaters concurrently electrically connected to the third driving circuit; wherein the hot-melt materials are at least divided into a plurality of first hot-melt materials, a plurality of second hot-melt materials and a plurality of third hot-melt materials.

7. The chip transferring method according to claim 6, wherein, when the red LED chip initial structures are randomly distributed in a first liquid substance of a first liquid receiving tank, the first micro heaters are concurrently driven by the first driving circuit so as to respectively heat the first hot-melt materials, and a viscosity of each of the first hot-melt materials is increased by heating of the corresponding first micro heater, so that the red LED chip initial structures are respectively adhered to the first hot-melt materials.

8. The chip transferring method according to claim 6, wherein, when the green LED chip initial structures are randomly distributed in a second liquid substance of a second liquid receiving tank, the second micro heaters are concurrently driven by the second driving circuit so as to respectively heat the second hot-melt materials, and a viscosity of each of the second hot-melt materials is increased by heating of the corresponding second micro heater, so that the green LED chip initial structures are respectively adhered to the second hot-melt materials.

9. The chip transferring method according to claim 6, wherein, when the blue LED chip initial structures are randomly distributed in a third liquid substance of a third liquid receiving tank, the third micro heaters are concurrently driven by the third driving circuit so as to respectively heat the third hot-melt materials, and a viscosity of each of the third hot-melt materials is increased by heating of the corresponding third micro heater, so that the blue LED chip initial structures are respectively adhered to the third hot-melt materials.

10. An image display device manufactured by the chip transferring method as claimed in claim 5, wherein the image display device comprises the substrate structure, an LED chip group and a conductive connection structure;
wherein the LED chip group includes a plurality of LED chip structures electrically connected to the circuit substrate, each of LED chip structures includes the LED chip main body, the first conductive electrode disposed on a bottom side of the LED chip main body, and the second conductive electrode disposed on a top side of the LED chip main body;
wherein the conductive connection structure includes the first conductive layers and the second conductive layers;
wherein each of the first conductive layers is electrically connected between the first conductive electrode of the corresponding LED chip structure and the circuit substrate, and each of the second conductive layers is electrically connected between the second conductive electrode of the corresponding LED chip structure and the circuit substrate;
wherein the first conductive layers are respectively made of the hot-melt materials, each of the hot-melt materials at least includes a first solder material and a second solder material, and a melting point of the first solder material is the same as or different from a melting point of the second solder material.

11. The image display device according to claim 10, wherein the circuit substrate includes a plurality of first conductive pads and a plurality of second conductive pads respectively corresponding to the first conductive pads, each of the first conductive layers is electrically connected between the first conductive electrode of the corresponding LED chip structure and the corresponding first conductive pad, and each of the second conductive layers is electrically connected between the second conductive electrode of the corresponding LED chip structure and the corresponding second conductive pad by wire bonding.

12. The image display device according to claim 11, wherein the micro heater group includes a first driving circuit, a second driving circuit, a third driving circuit and a plurality of micro heaters respectively corresponding to the first conductive layers, and the micro heaters are at least divided into a plurality of first micro heaters concurrently electrically connected to the first driving circuit, a plurality of second micro heaters concurrently electrically connected to the second driving circuit, and a plurality of third micro heaters concurrently electrically connected to the third driving circuit; wherein the hot-melt materials are at least divided into a plurality of first hot-melt materials, a plurality of second hot-melt materials and a plurality of third hot-melt materials.

13. The image display device according to claim 10, wherein the circuit substrate includes a plurality of first conductive pads and a plurality of second conductive pads respectively corresponding to the first conductive pads, each of the first conductive layers is electrically connected between the first conductive electrode of the corresponding LED chip structure and the corresponding first conductive pad, and each of the second conductive layers is extended from the second conductive electrode of the corresponding LED chip structure to the corresponding second conductive pad.

14. The image display device according to claim 13, wherein the conductive connection structure includes a plurality of electric insulating layers, and each of the electric insulating layers is disposed between the corresponding LED chip structure and the corresponding second conductive layer so as to insulate the first conductive layer and the second conductive layer from each other.

15. The image display device according to claim 14, wherein the micro heater group includes a first driving circuit, a second driving circuit, a third driving circuit and a plurality of micro heaters respectively corresponding to the first conductive layers, and the micro heaters are at least divided into a plurality of first micro heaters concurrently electrically connected to the first driving circuit, a plurality of second micro heaters concurrently electrically connected to the second driving circuit, and a plurality of third micro heaters concurrently electrically connected to the third driving circuit; wherein the hot-melt materials are at least divided into a plurality of first hot-melt materials, a plurality of second hot-melt materials and a plurality of third hot-melt materials.
